(19) United States
(12) Patent Application Publication
(10) Pub. No.: US 2014/0170857 A1
(43) Pub. Date: Jun. 19, 2014

(54) Customizing Etch Selectivity with Sequential Multi-Stage Etches with Complementary Etchants

(71) Applicant: INTERMOLECULAR, INC., San Jose, CA (US)

(72) Inventors: Chi-I Lang, Cupertino, CA (US); Shuogang Huang, San Jose, CA (US); Jeffrey Chih-Hou Lowe, Cupertino, CA (US); Robert Anthony Sculac, Lake Oswego, OR (US)

(73) Assignee: INTERMOLECULAR, INC., San Jose, CA (US)

(21) Appl. No.: 13/718,995

(22) Filed: Dec. 18, 2012

(51) Int. Cl. B44C 1/22; H01L 21/306

(52) U.S. Cl. CPC B44C 1/225; H01L 21/30604
USPC 438/749; 216/83

(57) ABSTRACT

A method of combinatorial processing involving etching a first material and a second material on a substrate comprising: etching the first material with a high first etch rate with a first etchant; etching the second material with a high second etch rate with a second etchant, wherein the first etchant and the second etchant are used sequentially without being separated by a rinse.

### FIELD OF THE DISCLOSURE

The present disclosure relates to a method of using multiple steps to simultaneously etch two different materials to accomplish a specified overall etch ratio with high etch rate. The method uses complementary etches which etch one material faster than the other material.

### BACKGROUND OF THE DISCLOSURE

Combinatorial processing permits fast evaluation of operations in the manufacture of semiconductor, solar, and green energy devices. Systems supporting combinatorial processing are sufficiently flexible to accommodate the demands of comparing many different processes both in parallel and in series.

Some exemplary operations include cleaning operations, additive operations, patterning operations, subtractive operations, and doping operations. These operations may be used in the manufacture of devices, such as integrated circuits (IC), semiconductors, flat panel displays, optoelectronics, data storage, packaged devices, and so on.

As dimensions of features on the devices continue to shrink, improvements are sought for materials, operations, processes, and sequences of these operations. Research and development (R&D) is typically conducted by running split lots on entire substrates. Unfortunately, this approach is costly and time-consuming.

Efficient experimentation in a timely and cost effective manner has become a highly desirable goal. In particular, combinatorial processing may be usefully applied to operations such that multiple experiments may be performed over a short period of time. Equipment for performing combinatorial processing and characterization should support the efficient data collection offered by the combinatorial processing operations.

In particular, different materials are etched at a high etch rate with a specified etch ratio to improve cycle time.

### SUMMARY OF THE DISCLOSURE

The following summary is included in order to provide a basic understanding of some aspects and features of the disclosure. This summary is not an extensive overview of the disclosure and as such it is not intended to particularly identify key or critical elements of the disclosure or to delineate the scope of the disclosure. Its sole purpose is to present some concepts of the disclosure in a simplified form as a prelude to the more detailed description that is presented below.

In some embodiments, using multiple steps to concurrently etch different materials improves equipment utilization and process cycle time for the operations in combinatorial processing. Most importantly, etching sequentially using etchants which vary in formulation and etch conditions is effective and efficient for combinatorial processing.

### BRIEF DESCRIPTION OF THE DRAWINGS

To facilitate understanding, identical reference numerals have been used, wherever possible, to designate identical elements that are common to the figures. The drawings are not to scale and the relative dimensions of various elements in the drawings are depicted schematically and not necessarily to scale.

The techniques of the present disclosure may readily be understood by considering the following detailed description in conjunction with the accompanying drawings, in which:

FIG. 1 is a schematic diagram for implementing combinatorial processing and evaluation using primary, secondary, and tertiary screening;

FIG. 2A is a schematic diagram for a general methodology for combinatorial process sequence integration that includes site-isolated processing and/or conventional processing;

FIG. 2B is a simplified schematic diagram illustrating an integrated high productivity combinatorial (HPC) system;

FIG. 3A is a simplified cross-sectional schematic view of a substrate processing tool, according to some embodiments of the present disclosure;

FIG. 3B is a perspective view of a processing chamber within the substrate processing tool of FIG. 3A;

FIG. 3C is a cross-sectional side view of an isolation unit body and a portion of a substrate within the substrate processing tool of FIG. 3A;

FIG. 3D is a plan view of the isolation unit body along line 3D-3D of FIG. 3C;

FIG. 4A is a cross-sectional view of an NMOS device and a PMOS device in a gate-last process flow; and

FIG. 4B-4C are schematic diagrams of complementary etches of two materials on a substrate.

### DETAILED DESCRIPTION

Methods of and apparatuses for combinatorial processing are disclosed. Methods of the present disclosure include introducing a substrate into a processing chamber. In some embodiments, methods include applying at least one subsequent process to each site-isolated region. In addition, methods include evaluating results of the films post processing.

Before the present disclosure is described in detail, it is to be understood that unless otherwise indicated this disclosure is not limited to specific layer compositions or surface treatments. It is also to be understood that the terminology used herein is for the purpose of describing particular embodiments only and is not intended to limit the scope of the present disclosure.

It must be noted that as used herein and in the claims, the singular forms “a,” and “the” include plural referents unless the context clearly dictates otherwise. Thus, for example, reference to “a layer” also includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the disclosure. The upper and lower limits of these smaller ranges may independently be included in the smaller ranges, and are also encompassed within the disclosure, subject to any specifically excluded limit in the stated range. Where the stated range includes one or both of the limits, ranges excluding either or both of those included limits are also included in the disclosure. The term “about” generally refers to ±10% of a stated value.

The term “site-isolated” as used herein refers to providing distinct processing conditions, such as controlled temperature, flow rates, chamber pressure, processing time, plasma composition, and plasma energies. Site isolation may provide complete isolation between regions or relative isolation between regions. Preferably, the relative isolation is sufficient to provide a control over processing conditions within ±10%, within ±5%, within ±2%, within ±1%, or within ±0.1% of the target conditions. Where one region is processed at a time, adjacent regions are generally protected from any exposure that would alter the substrate surface in a measurable way.

The term “site-isolated region” is used herein to refer to a localized area on a substrate which is, was, or is intended to be used for processing or formation of a selected material. The region may include one region and/or a series of regular or periodic regions predefined on the substrate. The region may have any convenient shape, e.g., circular, rectangular, elliptical, wedge-shaped, etc. In the semiconductor field, a region may be, for example, a test structure, single die, multiple dies, portion of a die, other defined portion of substrate, or an undefined area of a substrate, e.g., blanket substrate which is defined through the processing.

The term “substrate” as used herein may refer to any workpiece on which formation or treatment of material layers is desired. Substrates may include, without limitation, silicon, coated silicon, other semiconductor materials, glass, polymers, metal foils, etc. The term “substrate” or “wafer” may be used interchangeably herein. Semiconductor wafer shapes and sizes may vary and include commonly used round wafers of 2″, 4″, 200 mm, or 300 mm in diameter.

It is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need for consuming the equivalent number of monolithic substrates per material(s), processing condition(s), sequence(s) of processing conditions, sequence(s) of processes, and combinations thereof. This may greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006; U.S. Pat. No. 7,824,935 filed on Jul. 2, 2008; U.S. Pat. No. 7,871,928 filed on May 4, 2009; U.S. Pat. No. 7,902,063 filed on Feb. 10, 2006; and U.S. Pat. No. 7,947,531 filed on Aug. 28, 2009 which are all herein incorporated by reference for all purposes. Systems and methods for HPC™ processing are further described in U.S. patent application Ser. No. 11/352,077 filed on Feb. 10, 2006, claiming priority from Oct. 15, 2005; U.S. patent application Ser. No. 11/419,174 filed on May 18, 2006, claiming priority from Oct. 15, 2005; U.S. patent application Ser. No. 11/674,132 filed on Feb. 12, 2007, claiming priority from Oct. 15, 2005; and U.S. patent application Ser. No. 11/674,137 filed on Feb. 12, 2007, claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

In addition, systems and methods for combinatorial processing and further described in U.S. patent application Ser. No. 13/341,993 filed on Dec. 31, 2011 and U.S. patent application Ser. No. 13/302,730 filed on Nov. 22, 2011 which are all herein incorporated by reference for all purposes.

HPC™ processing techniques have been adapted to the development and investigation of absorber layers and buffer layers for TFPV solar cells as described in U.S. patent application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference for all purposes.

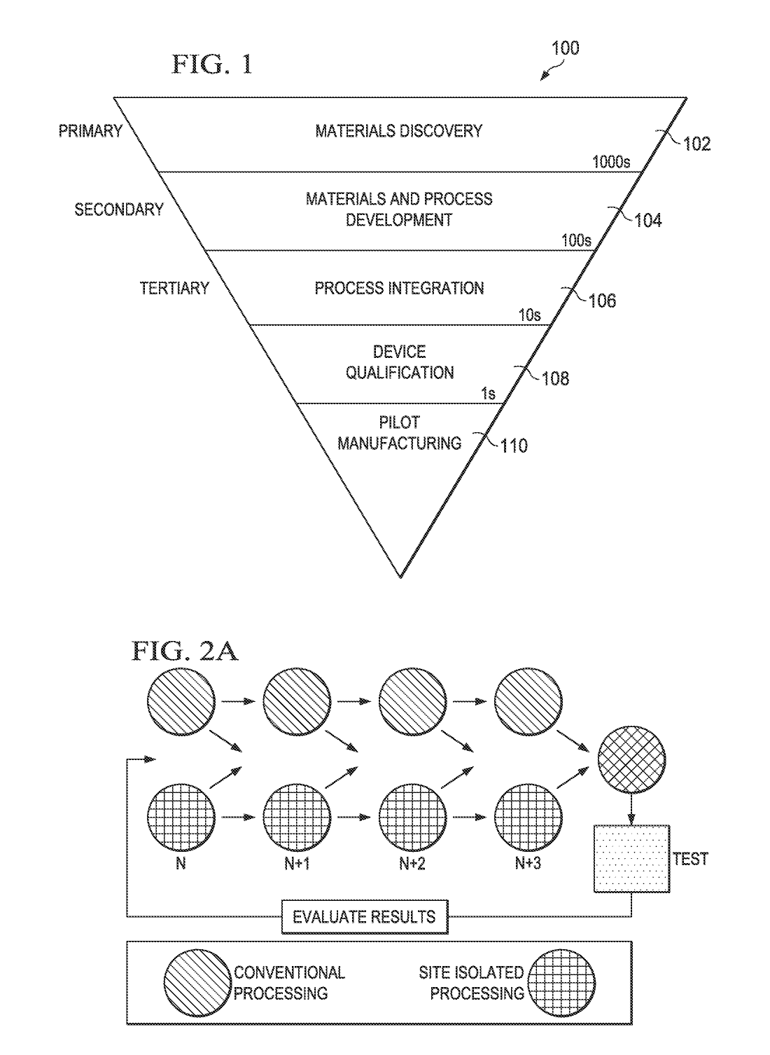

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages may be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e. microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes may proceed to pilot manufacturing 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from HPC™ techniques described in U.S. patent application Ser. No. 11/674,137 filed on Feb. 12, 2007 which is hereby incorporated for reference for all purposes. Portions of the '137 application have been reproduced below to enhance the understanding of the present disclosure.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete site-isolated region. Furthermore, while different materials or unit processes may be used for corresponding layers or steps in the formation of a structure in different site-isolated regions of the substrate during the combinatorial processing, the application of each layer or use of a given unit process is substantially consistent or uniform throughout the different site-isolated regions in which it is intentionally applied. Thus, the processing is uniform within a site-isolated region (intra-region uniformity) and between site-isolated regions (inter-region uniformity), as desired. It should be noted that the process may be varied between site-isolated regions, for example, where a thickness of a layer is varied or a material may be varied between the site-isolated regions, etc., as desired by the design of the experiment.

The result is a series of site-isolated regions on the substrate that contain structures or unit process sequences that have been uniformly applied within that site-isolated region and, as applicable, across different site-isolated regions. This process uniformity allows comparison of the properties within and across the different site-isolated regions such that the variations in test results are due to the varied parameter (e.g., materials, unit processes, unit process parameters, hardware details, or process sequences) and not the lack of process uniformity. In the embodiments described herein, the positions of the discrete site-isolated regions on the substrate may be defined as needed, but are preferably systematized for ease of tooling and design of experimentation. In addition, the number, variants and location of structures within each site-isolated region are designed to enable valid statistical analysis of the test results within each site-isolated region and across site-isolated regions to be performed.

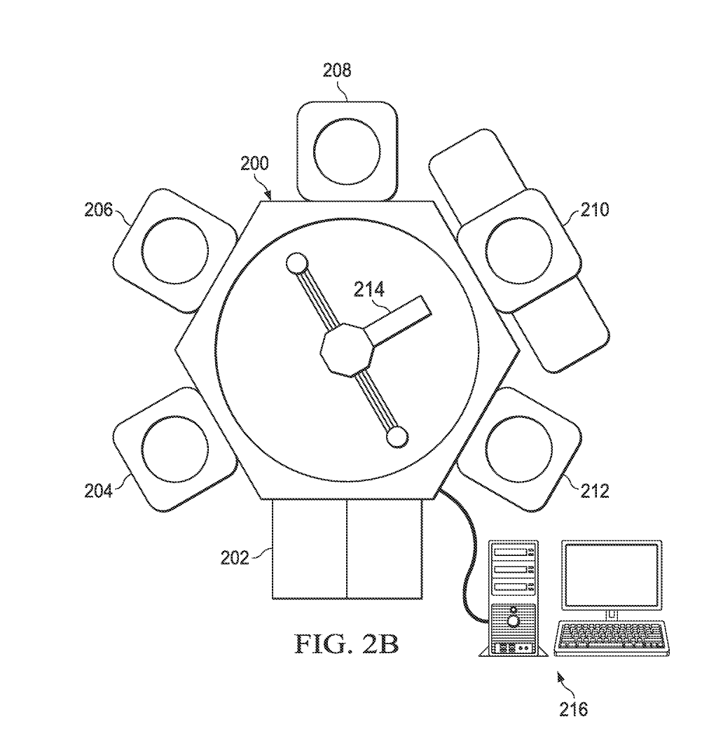

FIG. 2A is a simplified schematic diagram illustrating a general methodology for combinatorial process sequence integration that includes site-isolated processing and/or conventional processing. In some embodiments, the substrate is initially processed using conventional process N. In some exemplary embodiments, the substrate is then processed using site-isolated process N+1. During site-isolated processing, an HPC™ module may be used, such as the HPC module described in U.S. patent application Ser. No. 11/352,077 filed on Feb. 10, 2006, which is incorporated herein by reference for all purposes. The substrate may then be processed using site-isolated process N+2, and thereafter processed using conventional process N+3. Testing is performed and the results are evaluated. The testing may include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence may include processing the substrate using site-isolated process N, conventional processing for processes N+1, N+2, and N+3, with testing performed thereafter.

It should be appreciated that various other combinations of conventional and combinatorial processes may be included in the processing sequence with regard to FIG. 2A. That is, the combinatorial process sequence integration may be applied to any desired segments and/or portions of an overall process flow. Characterization, including physical, chemical, acoustic, magnetic, electrical, optical, etc. testing, may be performed after each process operation, and/or series of process operations within the process flow as desired. The feedback provided by the testing is used to select certain materials, processes, process conditions, and process sequences and eliminate others. Furthermore, the above flows may be applied to entire monolithic substrates, or portions of monolithic substrates such as coupons.

Under combinatorial processing operations the processing conditions at different site-isolated regions may be controlled independently. Consequently, process material amounts, reactant species, processing temperatures, processing times, processing pressures, processing flow rates, processing powers, processing reactant compositions, the rates at which the reactions are quenched, deposition order of process materials, process sequence steps, hardware details, etc., may be varied from site-isolated region to site-isolated region on the substrate. Thus, for example, when exploring materials, a processing material delivered to a first and second site-isolated regions may be the same or different. If the processing material delivered to the first site-isolated region is the same as the processing material delivered to the second isolated-region, this processing material may be offered to the first and second site-isolated regions on the substrate at different concentrations. In addition, the material may be deposited under different processing parameters. Parameters which may be varied include, but are not limited to, process material amounts, reactant species, processing temperatures, processing times, processing pressures, processing flow rates, processing powers, processing reactant compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used may be varied.

As mentioned above, within a site-isolated region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the site-isolated regions. It should be appreciated that a site-isolated region may be adjacent to another site-isolated region in some embodiments or the site-isolated regions may be isolated and, therefore, non-overlapping. When the site-isolated regions are adjacent, there may be a slight overlap wherein the materials or precise process interactions are not known, however, a portion of the site-isolated regions, normally at least 50% or more of the area, is uniform and all testing occurs within that site-isolated region. Further, the potential overlap is only allowed with material of processes that will not adversely affect the result of the tests. Both types of site-isolated regions are referred to herein as site-isolated regions or discrete site-isolated regions.

Substrates may be a conventional round 200 mm, 300 mm, or any other larger or smaller substrate/wafer size. In some embodiments, substrates may be square, rectangular, or any other shape. One skilled in the art will appreciate that substrate may be a blanket substrate, a coupon (e.g., partial wafer), or even a patterned substrate having predefined site-isolated regions. In some other embodiments, a substrate may have site-isolated regions defined through the processing described herein.

FIG. 2B is a simplified schematic diagram illustrating an integrated high productivity combinatorial (HPC) system. The HPC system includes a frame 200 supporting a plurality of processing modules. It will be appreciated that frame 200 may be a unitary frame in accordance with some embodiments. In some embodiments, the environment within frame 200 is controlled. A load lock 202 provides access into the plurality of modules of the HPC system. A robot 214 provides for the movement of substrates (and masks) between the modules and for the movement into and out of the load lock 202. Modules 204-212 may be any set of modules and preferably include one or more combinatorial modules. For example, module 204 may be an orientation/degassing module, module 206 may be a clean module, either plasma or non-plasma based, modules 208 and/or 210 may be combinatorial/conventional dual purpose modules. Module 212 may provide conventional clean or degas as necessary for the experiment design.

Any type of chamber or combination of chambers may be implemented and the description herein is merely illustrative of one possible combination and not meant to limit the potential chamber or processes that may be supported to combine combinatorial processing or combinatorial plus conventional processing of a substrate or wafer. In some embodiments, a centralized controller, i.e., computing device 216, may control the processes of the HPC system. Further details of one possible HPC system are described in U.S. patent application Ser. Nos. 11/672,473 and 11/672,478, the entire disclosures of which are herein incorporated by reference for all purposes. In a HPC system, a plurality of methods may be employed to deposit material upon a substrate employing combinatorial processes.

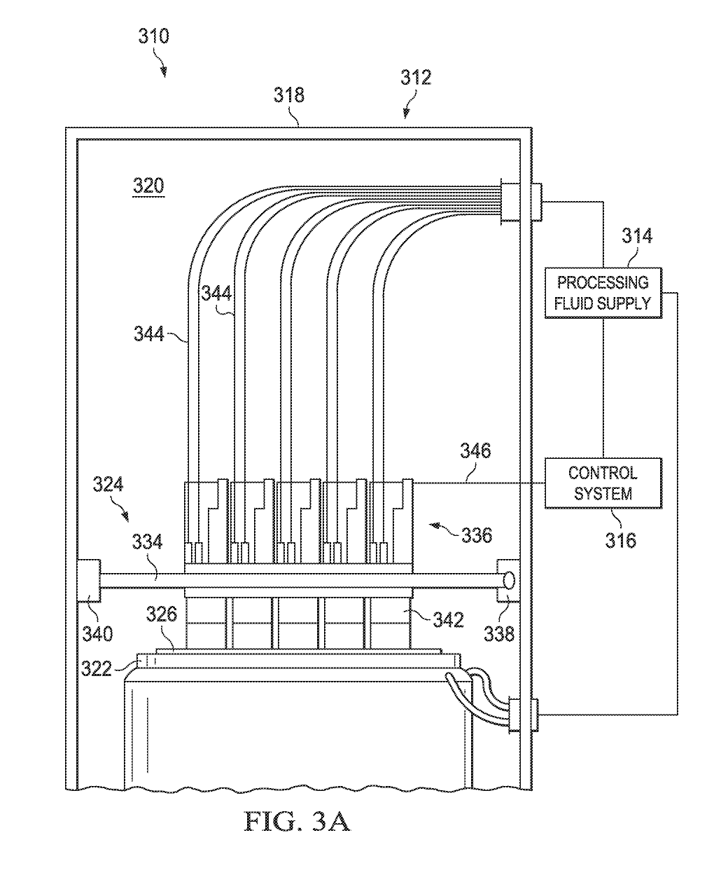

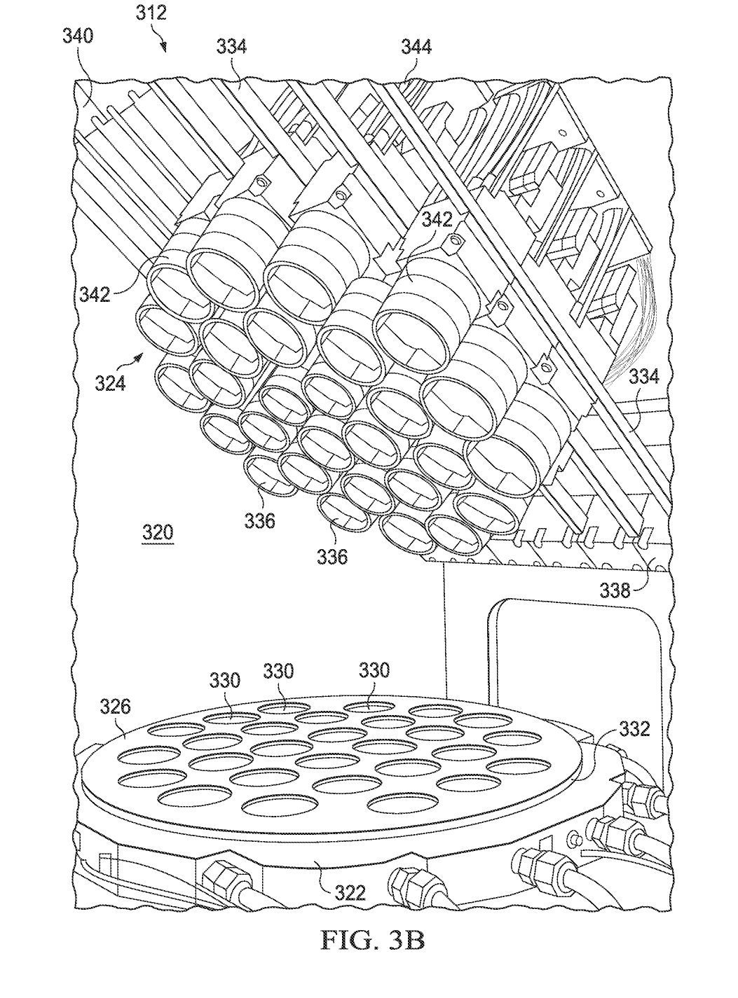

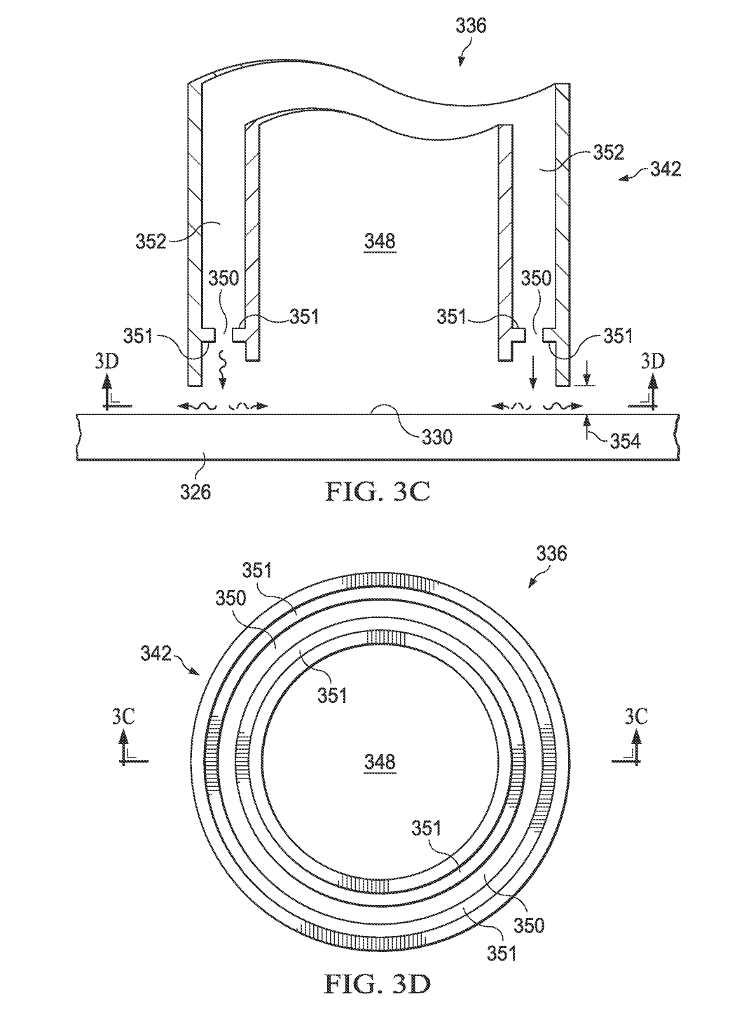

FIGS. 3A and 3B illustrate a substrate processing system 310. In some embodiments, the substrate processing system 310 may include a wet processing tool 312, a processing fluid supply 314, and a control system 316. The substrate processing system 310 shown in FIGS. 3A and 3B may perform processes on site-isolated regions 330 (on a substrate 326) which are separated by interstitial regions.

The wet processing tool 312 includes a housing 318, a processing chamber 320, a substrate support 322, and a wet processing assembly 324. The substrate support 322 is positioned within the processing chamber 320 and is configured to hold the substrate 326.

The substrate support 322 may be configured to secure the substrate 326 using a vacuum chuck, an electrostatic chuck, or another mechanism. Further, the substrate support 322 may be coupled to the housing 318 via an actuator, such as a pneumatic cylinder which is configured to move the substrate support 322 in a vertical direction to position substrate 326.

Referring specifically to FIG. 3B, the substrate 326 includes a plurality of site-isolated regions 330 on an upper surface limited by an outer edge 332. As is evident in FIG. 3B, the site-isolated regions 330 have widths (or diameters) that are considerably smaller than a width (or diameter) of the substrate 326. As described below, each of the site-isolated regions 330 may be processed by a corresponding one of multiple isolation units within the wet processing assembly 324. The portion(s) of the substrate 326 located outside the site-isolated regions 330 may be referred to as interstitial regions.

The substrate 326 may be a wafer having a diameter, such as 300 mm. In other embodiments, the substrate 326 may have other shapes, such as square or rectangular. It should be understood that the substrate 326 may be a blanket substrate (i.e., having a substantial uniform surface), a coupon (e.g., partial wafer), or even a patterned substrate having predefined regions, such as site-isolated regions 330. The site-isolated regions 330 may have a certain shape, such as circular, rectangular, elliptical, or wedge-shaped. A site-isolated region 330 may be, for example, a test structure, single die, multiple die, portion of a die, other defined portion of the substrate, or an undefined area of the substrate that may be subsequently defined through the processing.

As shown in FIG. 3B, the isolation units 336 may be arranged in rows or columns, with each of the isolation units 336 corresponding to one of the site-isolated regions 330 on the substrate 326. However, it should be understood that the number and arrangement of the isolation units 336 may differ, as is appropriate given the size and shape of the substrate 326 and the arrangement of the site-isolated regions 330. In some embodiments, each of the isolation units 336 includes a body, such as a container or reactor 342.

The substrate support 322 is then raised such that the bodies 342 of the isolation units 336 are located above the substrate 326. In some embodiments, the bodies 342 do not contact the substrate 326. More specifically, each of the isolation units 336 is positioned at a certain gap height over one of the site-isolated regions 330 on the substrate 326.

FIG. 3C shows the body 342 of one of the isolation units 336, as positioned above a corresponding site-isolated region 330 on the substrate 326. The body 342 is substantially cylindrical in shape and includes a central receptacle 348 and an annular trench outlet 350 extending into a lower surface of the body 342. In some embodiments, the central receptacle 348, like the body 342 itself, is substantially cylindrical in shape and positioned at a central portion of the body 342.

Although not specifically illustrated, the central receptacle 348 is in fluid communication with the processing fluid supply 314, via fluid lines 344 as shown in FIG. 3A. The trench outlet 350 is formed between annular protrusions 351 within the body 342 and symmetrically surrounds the central receptacle 348 and is in fluid communication with an annular plenum 352 which is in fluid communication with the processing fluid supply 314. Of particular interest is that the body 342 of the isolation unit 336 does not contact the upper surface of the substrate 326. In some embodiments, a gap height 354 is defined as a vertical distance between the lowest portion of the body 342 and the substrate 326. In some embodiments, the gap height 354 has a value in the range of 0.02-0.12 mm. In some embodiments, the gap height 354 may be as small as a few micrometers.

The body 342 is formed from a material that possesses proper bulk and surface properties. In some embodiments, the body 342 may be made of a chemically inert material, such as polytetrafluoroethylene (PTFE).

In operation, after the wet processing assembly 324 of FIG. 3B is lowered, a wet process, as is commonly understood, is performed on the site-isolated region(s) 330 on the substrate 326. Examples of wet processes that may be performed on the substrate 326 include wet cleanings, wet etches and/or strips, and electroless depositions.

Referring to FIGS. 3C and 3D, the operation of the wet processing apparatus 312, illustrated in FIG. 3B, will now be described with respect to one of the isolation units 336. However, it should be understood that all of the isolation units 336 may be similarly operated at the same time.

In order to create a barrier around the site-isolated region 330, a fluid (hereinafter referred to as a “barrier fluid”), such as argon or nitrogen gas, is delivered to the annular plenum 352 in the body 342 of each of the isolation units 336 by the processing fluid supply 314. The barrier fluid flows from the annular plenum 352 through the annular trench outlet 350 and onto the substrate 326, where it flows both inwards towards the center of the respective site-isolated region 330 on the upper surface of the substrate 326 and outwards, away from the site-isolated region 330. This gas flow creates an annular fluid barrier around the respective site-isolated region 330 on the substrate that prevents processing fluid (e.g., a liquid) on the substrate 326 from passing between the site-isolated region 330 and the interstitial portion of the substrate 326.

Still referring to FIGS. 3C and 3D, a processing fluid (e.g. a liquid), such as a cleaning solution, is then delivered to the central receptacle 348 of the body 342 from the processing fluid supply 314 of FIG. 3A. The liquid flows onto the respective site-isolated region 330 on the substrate 326, where it is restricted from flowing onto the interstitial portion of the substrate 326 by the fluid barrier. As such, as the processing liquid continues to flow into the central receptacle 348, a column of liquid is formed within the isolation unit 336 over the respective site-isolated region 330 of the substrate 326.

It should be understood that although the barrier fluid may cover the region 330 on the substrate 326 before the processing fluid is delivered into the central receptacle 348, this portion of the barrier may have a relatively low pressure such that the processing fluid pushes it back, substantially off the site-isolated region 330. In contrast, the portion(s) of the barrier directly under the annular trench outlet 350 may have a relatively high pressure, preventing the processing fluid from passing between the site-isolated region 330 and the interstitial portion of the substrate 326. It should also be understood that in some embodiments, as described below, the flow of the barrier fluid may be reversed, such as for processing the interstitial portion of the substrate 326.

After a predetermined amount of time (i.e., depending on the particular wet process being performed), the liquid may be removed from the central receptacle 348 by the processing fluid supply 14 (i.e., a vacuum supply). As such, the present disclosure allows for wet processes to be performed on only particular portions of the substrate 326, without any of the components of the tool 310 contacting the upper surface of the substrate 326. Thus, the likelihood that any contaminates will be left on the substrate 326 are reduced.

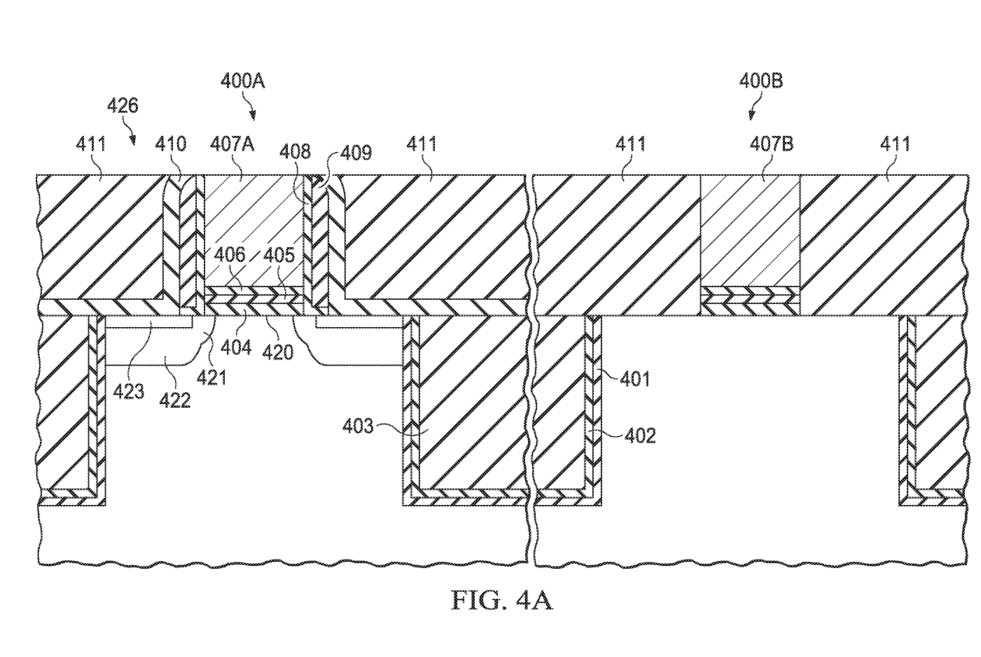

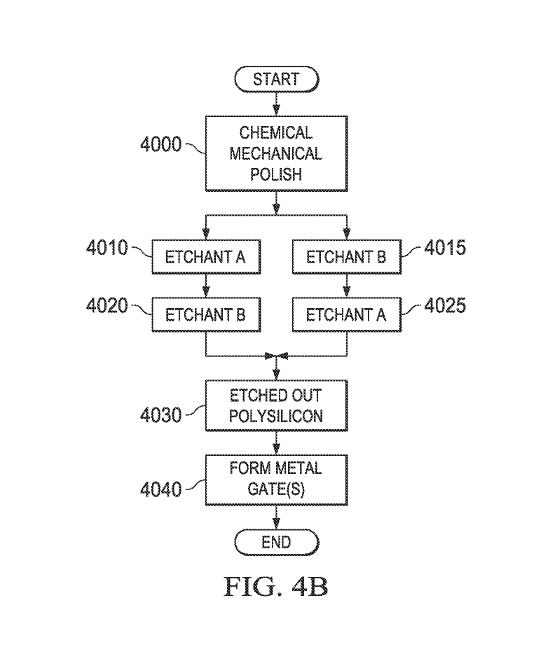

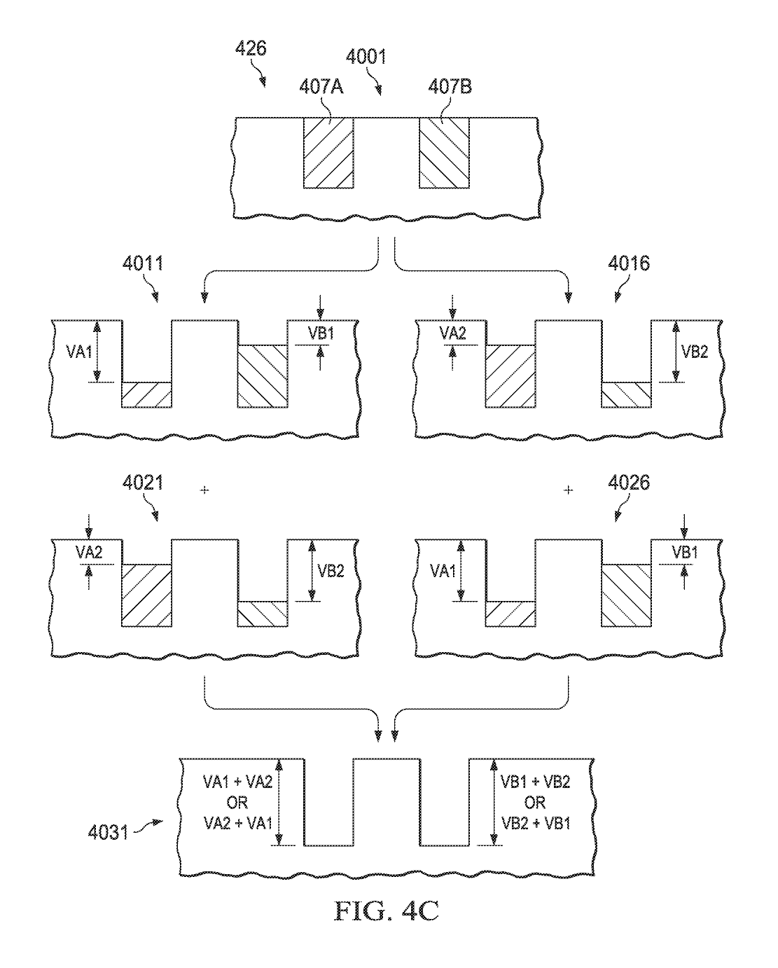

A device may be formed in the substrate 326, as shown in some embodiments in FIG. 4A. In some embodiments, a first device includes an n-type field effect transistor (NFET), such as an n-type metal-oxide-semiconductor (NMOS.) FET 400A. In some embodiments, a second device includes a p-type field effect transistor (PFET), such as a p-type metal-oxide-semiconductor (PMOS) FET. 400B

The NMOS 400A device and the PMOS 400B device may be used in a complementary metal-oxide-semiconductor (CMOS) integrated circuit IC). The first device and the second device may be formed by using various processes as described below. In some embodiments, the first device and the second device may differ in a few processes so as to reduce cost. In some embodiments, the first device and the second device may differ in many processes so as to increase performance.

First, a pad oxide layer is grown thermally at a temperature selected from a range of about 850-1,150 degrees Centigrade. The oxidizing agent may include O₂ gas. The pad oxide layer has a thickness selected from a range of about 8-30 nm.

Then, an oxidation barrier layer, such as a silicon nitride layer, is formed over the pad oxide layer. The silicon nitride layer may be formed by chemical vapor deposition (CVD) at a temperature selected from a range of about 670-830 degrees Centigrade. The silicon nitride layer may be formed from a reaction of silane and ammonia, such as at atmospheric pressure. The silicon nitride layer may also be formed from a reaction of dichlorosilane and ammonia, such as at a sub-atmospheric, or low, pressure. The silicon nitride layer has a thickness selected from a range of about 65-150 nm.

The silicon nitride layer may be used as part of a trench liner, such as for shallow trench isolation (STI). The silicon nitride layer may also be used as a polish stop, such as for chemical-mechanical polish (CMP). The silicon nitride layer may further be used as an etch stop, such as for reactive ion etch (RIE).

In some embodiments, the pad oxide layer serves as a stress buffer layer for the overlying silicon nitride layer. Otherwise, the high tensile stress in the silicon nitride layer may generate severe crystal dislocations in the underlying silicon substrate during subsequent thermal processing.

The processes of photolithography and etch may be used to pattern the isolation layer on the substrate. In some embodiments, the isolation layer may include STI. First, a radiation-sensitive material, such as a photoresist, may be applied or coated over the silicon nitride layer. Next, a reticle for the isolation layer is placed in a path of radiation of appropriate wavelength, energy, and dose to determine the portion of the photoresist that is to be exposed. The exposure is performed in a wafer aligner, stepper, or scanner. Exposure is followed by a development of the photoresist, such as in an alkaline aqueous solution, to create a mask on the wafer.

The mask has a feature that corresponds to the exposed portion of the photoresist. The shape and Critical Dimension (CD) of the feature in the photoresist is derived from a design on the isolation-layer reticle. Next, the feature that has been patterned in the photoresist may be transferred into underlying layers.

A RIE plasma process may be used to form an opening in the composite stack of silicon nitride layer over pad oxide layer. A high-density plasma, such as a radio frequency (RF) inductively-coupled plasma (ICP), may be used. The dry etch to form the opening may be performed with a gas mixture that includes an etching gas, such as CF₄, and a polymerizing gas, such as CH₂F₂. The etching gas serves as the principal source of fluorine for etching while the polymerizing gas improves selectivity by passivating the sidewalls of the opening during the etch. The etch selectivity of the silicon nitride layer and the pad oxide layer relative to the photoresist may be about 20:1 or greater. Other gases that may be used for etching the opening include C₃F₆ and CHF₃. The etch rate of the silicon nitride layer and the pad oxide layer may be selected from a range of about 30-200 nm per minute.

The photoresist is stripped off and a shallow trench etch is performed using the silicon nitride layer as a hard mask. In some embodiments, the etch selectivity to photoresist is high enough so the silicon nitride, the pad oxide, and the trench may be etched, consecutively, without first stripping the photoresist.

A low-pressure, high-density plasma etch, such as with Cl₂/Ar, may be used to etch a trench into the silicon substrate. Depending on the trench fill process to be used, the angle of the sidewall of the trench may be selected from a range of about 70-90 degrees.

After trench etch, a liner oxide 401 is grown thermally to serve several purposes. First, the liner oxide 401 removes damage that may have resulted from the trench etch. Second, the liner oxide 401 enhances corner rounding at the top and bottom of the trench to minimize stress upon oxide fill 403. Third, the liner oxide 401 controls sub-threshold leakage by preventing gate wraparound. Fourth, the liner oxide 401 provides an interface for depositing the oxide fill 403.

In some embodiments, the liner oxide 401 layer has a thickness selected from a range of about 8-15 nm. A liner nitride 402 layer may be formed over the liner oxide 401 layer to create a composite stack 401, 402 prior to filling the trench.

Next, the trench may be filled with a dielectric material, such as an oxide 403, using CVD. The gapfill 403 must be able to fill a shallow trench with a depth:width aspect ratio of 6:1 or greater. The trench may be overfilled by 20-50%. The oxide 403 may be densified by annealing so as to endure subsequent CMP, wet etches, and cleans. In some embodiments, annealing the gapfill 403, such as at a temperature of about 1,000-1,100 degrees Centigrade, may reduce the wet etch rate of the gapfill 403 by about 20%.

The shallow trench isolation is planarized with CMP. The CMP may be performed using a slurry with a high pH, such as about 10.0-11.0, in conjunction with abrasives, such as very fine silica or alumina particles. The high pH will hydroxylate the oxide 401 403, but not the nitride 402. The silica particles will mechanically abrade both oxide 401, 403 and nitride 402. Planarization of the gapfill 403 occurs because the effective pressure exerted on elevated features is higher than the effective pressure exerted on recessed areas. However, the polish pad is not infinitely stiff so excessive thinning, or dishing, of the gapfill 403 in the middle of wide exposed regions may occur. The dishing may be highly pattern-dependent.

In some embodiments, the CMP must remove all the gapfill 403 (oxide layer) over the active area without eroding too much of the underlying polish stop (liner nitride 402 layer). In other words, the gapfill-to-polish stop selectivity must be high enough to minimize dishing of the gapfill 403 (oxide layer) and erosion of the polish stop (liner nitride 402 layer).

After the formation of the shallow trench isolation, the composite stack 401, 402 outside the STI is removed. First, buffered hydrofluoric acid, such as 5:1 BHF, may be used to remove a thin layer of oxynitride that may have formed (over the liner nitride 402 layer) outside the STI. Next, the liner nitride 402 layer outside the STI is removed with phosphoric acid, such as 85% phosphoric acid, at about 160-180 degrees Centigrade from a reflux boiler. Then, the liner oxide 401 layer outside the STI is removed with hydrofluoric acid. The result is an isolation region that separates adjacent active regions. In some embodiments, part or all of the composite stack 401, 402 outside the STI may be removed by a dry etch process instead of the wet etch process described above.

If desired, a thin layer of sacrificial oxide may be grown over the silicon substrate in the active regions. A wet etch of the sacrificial oxide will remove any damage in the silicon substrate. Etching off the sacrificial oxide will also remove any silicon oxynitride that may have formed (over the silicon) near the edges of the liner nitride 402 (Kooi effect) during an oxidation. Otherwise, silicon oxynitride may interfere with the subsequent formation of a gate dielectric stack, resulting in thin and non-uniform spots.

An ultra-low energy ion implantation may be used to adjust the threshold voltage, Vₜ, in a channel 420 of the device. Then a gate dielectric stack 404, 405, 406 may be formed over the silicon in the channel 420.

In some embodiments, the gate dielectric stack 404, 405, 406 may include an amorphous high-k (greater than about 15) 405 gate dielectric, such as hafnium oxide (HfO₂), formed with metal-organic chemical vapor deposition (MOCVD) or atomic layer deposition (ALD). The gate dielectric 405 may have a physical thickness of about 0.6-1.5 nm.

Some thin layers 404, 406 may be used at interfaces as buffer layers, spacer layers, and barrier layers to address one or more device performance issues, such as interdiffusion and reaction.

Some thin layers 404, 406 may be used at interfaces as buffer layers, spacer layers, and barrier layers to address one or more device reliability issues, such as stress, cracking, and delamination.

Some thin layers 406 may be used at interfaces as capping layers, and etch stop layers (ESL) to address one or more process issues, such as adhesion and low etch selectivity.

Next, a gate electrode 407A is formed over the gate dielectric stack 404, 405, 406. In some embodiments, the gate electrode 407A may have one (planar) surface (such as an upper surface) to control the channel 420 region.

In some embodiments, the gate electrode) may have two surfaces (such as a left side surface and a right side surface) to control the channel region.

In some embodiments, the gate electrode may have three surfaces (such as an upper surface, a left side surface, and a right side surface) to control the channel region.

In some embodiments the gate electrode may have four surfaces (such as an upper surface, a left side surface, a right side surface, and a lower surface) to control the channel region. Surrounding the channel region on two or more sides, such as in a finFET, helps to make the electric field more uniform throughout the channel region.

In some embodiments, the transistor may include multiple gate electrodes, such as in a mugFET, to obtain better electrostatic integrity to suppress Short-Channel Effects (SCE) and increase current drive capability.

For simplicity of exposition, the following description will be based on some embodiments based on a bulk CMOS technology with a planar gate electrode 407A. In some embodiments, the gate electrode 407A may have a thickness of 40-65 nm.

A gate-last process flow may include a replacement gate process. The temporary dummy gate electrode 407A may be formed from polycrystalline silicon or polysilicon. The polysilicon may be formed using CVD at atmospheric pressure. In some embodiments, the CVD may be performed at low pressure (sub-atmospheric) to improve step coverage, increase uniformity, increase throughput, and reduce particulate contamination. Furthermore, the CVD may be plasma-enhanced with R.F. power to decrease process temperature.

Silane may be pyrolyzed (dissociated at high temperature) to deposit silicon. Silicon deposited above 600 degrees Centigrade will have a polycrystalline structure. The polysilicon exhibits a columnar grain structure with a grain size of about 30 nm at a lower surface increasing up to about 100 nm at an upper surface. A higher deposition temperature will favor a shift in a preferred crystalline orientation from {110} to {100}.

The polysilicon may be doped intrinsically (in-situ during deposition) or extrinsically (ex-situ with diffusion or ion implantation followed by anneal). Doping reduces resistivity of the gate electrode. The dopant may be p-type (such as boron) or n-type (such as arsenic or phosphorus).

The gate electrode 407A may be patterned by photolithography and etch. In some embodiments, the physical gate length may be selected from a range of about 25-50 nm. After patterning, the temporary dummy gate electrode 407A is used to self-align an ultra-low energy ion implantation (followed by spike anneal) to form lightly-doped drains (LDD) or tips (or extensions) 421 for the source/drain 422 on opposing sides of the gate electrode 407A. Tilted implants may be performed if desired. In some embodiments, plasma (or gas phase) doping may be used. The source/drain extensions 421 may have a junction depth selected from a range of about 10-20 nm.

A sidewall spacer 408, 409 with a thickness selected from a range of about 25-80 nm may be formed on both sides of the gate. The sidewall spacer 408, 409 may include one or more layers of dielectric materials. In some embodiments, the sidewall spacer includes at least one of the following dielectric materials: oxide, nitride, and oxynitride. The dielectric materials may be formed thermally or by CVD.

A raised source/drain 422 may be formed next to the sidewall spacer 408, 409 on both sides of the gate electrode 407A with selective epitaxial deposition. The raised source/drain 422 improves silicide 423 formation and reduces parasitic capacitance.

The temporary dummy gate electrode 407A with sidewall 408, 409 is used to self-align implants to dope the source/drain 422. In some embodiments, plasma or gas phase doping may be used. The raised source/drain 422 may have a junction depth selected from a range of about 20-40 nm.

Salicide (self-aligned silicide) 423 with a thickness selected from a range of about 15-25 nm may be formed over the raised source and drain. In some embodiments, nickel silicide (NiSi) reduces contact leakage and consumes less silicon than cobalt silicide (CoSi₂).

This is followed by deposition of an etch stop 410 layer (ESL) (for a subsequent contact etch) and a first inter-layer dielectric (ILD) 411. The ILD 411 layer may be formed over the device on the substrate 426. The ILD 411 may be formed from a low-k (dielectric constant) material, such as organosilicate glass (OSG) or carbon-doped oxide (CDO). The low-k material may have a value selected from a range of 1.0-2.2. The low-k material may be applied by spin-on or deposited by CVD. The ILD 411 may be porous or include an air gap.

Then, as shown in block 4000 in FIG. 4B, CMP is used to planarize the ILD 411 and open up the top of the gate electrode 407A. Next, the temporary dummy gate electrode 407 is etched out. In some embodiments, the polysilicon is etched with a plasma etch.

In some embodiments as shown in FIG. 4B, the polysilicon (solid) is etched with a wet etch. Wet etching may be performed by immersion or spraying. During immersion etching, a masked (or unmasked) substrate is submerged in a solution (that is stirred inside a covered stationary tank). During spray etching, the masked (or unmasked) substrate is sprayed with a solution ((inside an enclosed chamber that may be stationary or rotating).

Wet etching the solid in the solution, whether by immersion or spraying, is a heterogeneous process. The consecutive steps may include diffusion of the reacting molecules from solution, adsorption of the reacting molecules on the surface of the solid, formation of a surface complex, dissociation of the complex into reaction products, desorption of the reaction products, and diffusion of the reaction products into solution.

In particular, wet etching polysilicon may require careful adherence to a documented procedure in order to achieve a reproducible process. For example, the etchant may have to be mixed in a particular way while using certain types of containers. Then, the etchant may have to be aged for a certain duration before being used for a first time.

The etchant is sensitive to loading, such as of byproducts of the etch process. As a result, the etch rates and the etch selectivity are dependent on history.

The useful life of the etchant is also short. Thus, the wet etch solution must be discarded and replaced after a certain period of time.

Furthermore, immersion wet etching is affected by carryover of liquids and dead spots in the tank. In contrast, spray wet etching is affected by air flow fluctuations and thermal gradients.

FIG. 4B shows some embodiments of the method of sequential multi-stage etch of the same substrate with complementary etchants. The term complementary refers to a condition in which each etchant complements the other etchants by predominantly and preferentially etching one of the many materials exposed on the substrate.

The substrate may have two or more materials exposed, such as a first material, a second material, a third material, etc. First, select two or more complementary etchants. For example, obtain a first etchant that etches the first material with a high etch rate, a second etchant that etches the second material with a high etch rate, a third etchant which etches the third material with a high etch rate, etc. In some embodiments, a high etch rate may include 10-20 nm per minute.

The etchants may differ in at least one of the following; chemically active components, concentration of the components, process temperature, other etch condition or parameter, etc. The etchants may be aqueous (dissolved in water) or non-aqueous. The etchants may be acidic (pH lower than 7.0) or alkaline (pH higher than 7.0). The etchants may be organic (including carbon-based compounds) or inorganic.

Many wet etch reactions involve oxidation and reduction. In some embodiments, the wet etchant for polysilicon includes hydrogen peroxide and ammonium hydroxide. Hydrogen peroxide is an oxidizing agent that decomposes into oxygen and water. Ammonium hydroxide is an alkaline solution that decomposes into ammonia and water.

Second, determine an etch time for each etchant so as to customize the overall (or effective or net) etch ratio (or selectivity) for two or more of the materials. In some embodiments, the etch selectivity for two materials may be 1.0:0.8 or 1.0:1.0 (i.e., no selectivity) or 1.0:1.2.

The etchant may be isotropic (equivalent in all orientations) or anisotropic. The choice of the etchant may depend on whether the materials being etched on the substrate have bulk properties which are isotropic or anisotropic.

Third, use the desired etchants sequentially, such as in different or multi-stages. Each stage may involve a different tank (or chamber or tool). Alternatively, each stage may involve the same tank (or chamber or tool), but separated in time by a rinse (or flush or purge).

In some embodiments, two materials on the substrate may be etched simultaneously in several sequential steps (or stages). The substrate may include undoped and doped polysilicon. In some embodiments, the doping is light (n+ or p+), such as 10¹⁷-10¹⁸ atoms per cubic centimeter. In some embodiments, the doping is heavy (n++ or p++), such as 10¹⁹-10²⁰ atoms per cubic centimeter.

In some embodiments, the two materials on the substrate may include n-doped polysilicon and p-doped polysilicon. N-type dopants may include arsenic or phosphorus. P-type dopants may include boron. In some embodiments boron-doped silicon has a significantly lower etch rate than undoped polysilicon in aqueous alkaline solutions.

In some embodiments, the etchants may differ in concentration of the components, such as 3.0% vs. 4.5% hydrogen peroxide and 2.0% vs. 3.0% ammonium hydroxide.

In some embodiments, the etchants may differ in process temperature, such as 30 degrees Centigrade vs. 45 degrees Centigrade.

FIG. 4C shows an example where two materials 407A, 407B are exposed on the same substrate 426, such as in a replacement polysilicon process in a gate-last process flow.

As shown in block 4000 in FIG. 4B, the two materials may be planarized first with a CMP process. The goal, as shown in block 4030 of FIG. 4B, is to etch out the dummy polysilicon 407A, 407B to form a structure 4031 as shown in FIG. 4C.

In some embodiments, efficiency may be increased by specifying a 1:1 etch selectivity for the two materials 407A, 407B. This will minimize an overetch of the faster etching material in order to accommodate the slower etching material.

Two complementary etchants A, B may be selected and used to accomplish this result. The etch rates of the various materials (in the single etchant in each stage) are selected to be significantly different.

On the one hand, as shown in blocks 4011, 4026 in FIG. 4C, etchant A etches material 407A very quickly to remove volume VA1, but etches material 407B very slowly to remove volume VB1.

On the other hand, as shown in blocks 4016, 4021 in FIG. 4C, etchant B etches material 407B very quickly to remove volume VB2, but etches material 407A very slowly to remove volume VA2.

In some embodiments, as shown in FIG. 4C, use of etchant A in a first stage 4011, followed sequentially by use of etchant B in a second stage 4021 may accomplish the desired 1:1 selectivity with high effective etch rates for both material 407A and material 407B.

In some embodiments, as shown in FIG. 4C, use of etchant B in a first stage 4016, followed sequentially by use of etchant A in a second stage 4026 may accomplish the desired 1:1 selectivity with high effective etch rates for both material 407A and material 407B.

If the complementary etchants A, B act (or operate) independently, the sequential etches may be decoupled. Then, the order of the sequential etches (and stages) do not matter and, as shown in the structure 4031 in FIG. 4C, the same result will be obtained regardless of the order that the etchants are used. However, if the complementary etchants affect (or influence) each other, then one order may be more effective than the other order.

If the etchants A, B from each stage do not interfere with each other, the sequential etches do not have to be separated with a flush, purge, or rinse. However, if the etchants A, B from each stage do interfere with each other, the sequential etches do have to be separated with a flush, purge, or rinse.

Next, as shown in block 4040 in FIG. 4B, a metal is formed over the high-k gate dielectric stack 404, 405, 406. The gate-last process flow allows use of metal for the gate electrode 407A since the metal need not be exposed to the high temperatures that occur early in the process flow, such as for oxidations and anneals. Using a metal gate electrode also avoids a depletion effect characteristic of a doped polysilicon gate electrode.

In some embodiments, the gate electrode 407A includes a single metal. Although more elaborate than a gate-first process flow, the gate-last process flow also allows use of separate metals to optimize different work functions for the NMOS 400A and PMOS 400B transistors of FIG. 4A. In some embodiments, the gate electrode 407A may further include double metal, such as Tantalum or Titanium for the NMOS transistor 400A and Tantalum Nitride, Tungsten Nitride, or Titanium Nitride for the PMOS transistor 400B.

After completion of the processing of the high-k 405 metal gate electrode 407A, a dual-damascene scheme with CMP may be used to form multilayer interconnects for the device with a metal, such as copper, or an alloy. As needed, diffusion barrier layers and shunt layers may be included for the vias and metal lines.

Methods and apparatuses for combinatorial processing have been described. It will be understood that the descriptions of some embodiments of the present disclosure do not limit the various alternative, modified and equivalent embodiments which may be included within the spirit and scope of the present disclosure as defined by the appended claims. Furthermore, in the detailed description above, numerous specific details are set forth to provide an understanding of various embodiments of the present disclosure. However, some embodiments of the present disclosure may be practiced without these specific details. In other instances, well known methods, procedures, and components have not been described in detail so as not to unnecessarily obscure aspects of the present embodiments.

What is claimed is:

1. A method for combinatorial processing of semiconductor substrates, the method comprising:
providing a semiconductor substrate comprising multiple site-isolated regions, wherein each site-isolated region comprises a first material and a second material;
exposing each site-isolated region to two wet etchants, wherein the two wet etchants comprise the same components;
varying concentrations and temperatures of the two wet etchants in a combinatorial manner to alter etching selectivity between the first material and the second material in the multiple site-isolated regions,
selecting a first set of conditions wherein the first material etches faster than the second material; and
selecting a second set of conditions wherein the second material etches faster than the first material.

2. The method of claim 1 wherein the first material and the second material have an effective etch selectivity of 1:1 after etching with both the first set of conditions and the second set of conditions.

3. The method of claim 1 wherein a specified effective etch selectivity may be achieved by adjusting an etch rate for at least one of the materials for at least one of the first set of conditions or the second set of conditions.

4. The method of claim 1 wherein a specified effective etch selectivity may be achieved by adjusting an etch time for at least one of the materials for at least one of the first set of conditions or the second set of conditions.

5. The method of claim 1 wherein the same components comprise hydrogen peroxide and ammonium hydroxide.

6. The method of claim 1 wherein the first material and the second material comprise polysilicon with different types of doping.

7. A method of wet etching two materials disposed on a substrate under two sets of conditions wherein a first material is etched faster than a second material under a first set of conditions and the second material is etched faster than the first material under a second set of conditions.

8. The method of claim 7 wherein the two sets of conditions are not separated with a rinse.

9. The method of claim 7 wherein the wet etching comprises spray etching.

10. The method of claim 7 wherein the two materials are etched with an effective etch selectivity of 1:1 after wet etching with the two sets of conditions.

11. The method of claim 7 wherein the two sets of conditions are separated with a rinse.

12. The method of claim 7 wherein the two materials comprise polysilicon with different types of doping.

13. A method of etching two materials on a substrate in both a first stage and in a second stage with complementary etchants in the two stages wherein the complementary etchants comprise the same components.

14. The method of claim 13 wherein the complementary etchants differ in concentration of the same components.

15. The method of claim 13 wherein the complementary etchants differ in temperature.

16. The method of claim 13 wherein the two materials comprise polysilicon with different types of doping.

17. The method of claim 13 wherein the etching comprises immersion etching.

18. The method of claim 13 wherein the etching comprises spray etching.

19. The method of claim 13 wherein the etching is followed by a rinse.

20. The method of claim 13 wherein the etching provides etch rates between 10 nm per minute and 20 nm per minute and an effective etch selectivity of 1:1.
